(19) United States
(12) Patent Application Publication
(10) Pub. No.: US 2023/0005814 A1
(43) Pub. Date: Jan. 5, 2023

(54) SEMICONDUCTOR PACKAGE INCLUDING HEAT SINKS

(71) Applicant: SAMSUNG ELECTRONICS CO., LTD., SUWON-SI (KR)

(72) Inventors: HYUNSOO CHUNG, HWASEONG-SI (KR); YOUNGLYONG KIM, ANYANG-SI (KR); INHYO HWANG, ASAN-SI (KR)

(21) Appl. No.: 17/705,931

(22) Filed: Mar. 28, 2022

(30) Foreign Application Priority Data
Jul. 2, 2021 (KR) 10-2021-0087399

(51) Int. Cl. H01L 23/427; H01L 23/498

(52) U.S. Cl. CPC H01L 23/427; H01L 23/49838

(57) ABSTRACT

A semiconductor package includes an interposer, a first semiconductor chip attached onto the interposer, second semiconductor chips stacked on the first semiconductor chip, at least two heat sinks mounted on the interposer and spaced apart from the second semiconductor chips, and a molding layer surrounding the second semiconductor chips and the at least two heat sinks.

### CROSS-REFERENCE TO RELATED APPLICATION

This application claims priority under 35 U. S. C. § 119 to Korean Patent Application No. 10-2021-0087399 filed on Jul. 2, 2021 in the Korean Intellectual Property Office, the subject matter of which is hereby incorporated by reference in its entirety.

### BACKGROUND

The inventive concept relates generally to semiconductor packages, and more particularly, to semiconductor packages including heat sinks.

Consumer demands for increased performance result in continuing pressure for improvements in related semiconductor devices. Accordingly, contemporary and emerging semiconductor devices are expected to provide increased performance at higher operating speeds over an expanding range of functionality.

In response to these demands, semiconductor packages including multiple semiconductor chips have been developed to provide dramatically improved performance. However, the thermal energy (or heat) generated by semiconductor chips within a semiconductor package has become a notable design consideration.

### SUMMARY

Embodiments of the inventive concept provide semiconductor packages including a heat sink capable of efficiently exhausting heat generated by constituent semiconductor chips.

According to one aspect of the inventive concept, a semiconductor package may include; an interposer, a first semiconductor chip mounted on the interposer, stacked second semiconductor chips vertically disposed on the first semiconductor chip, a first dummy chip horizontally disposed on the interposer to one side of the first semiconductor chip, a second dummy chip horizontally disposed on the interposer to another side of the first semiconductor chip opposing the one side of the first semiconductor chip, a first heat sink thermally-mounted on the first dummy chip and horizontally spaced apart to one side of the stacked second semiconductor chips, a second heat sink thermally mounted on the second dummy chip and horizontally spaced apart to another side of the stacked second semiconductor chips opposing the one side of the stacked second semiconductor chips, and a molding layer surrounding the stacked second semiconductor chips, the first heat sink, and the second heat sink.

According to another aspect of the inventive concept, a semiconductor package may include; an interposer, a first semiconductor chip mounted on the interposer, stacked second semiconductor chips vertically disposed on the first semiconductor chip, a first heat sink thermally-mounted on the interposer and horizontally spaced apart to one side of the first semiconductor chip, a second heat sink thermally-mounted on the interposer and horizontally spaced apart to another side of the first semiconductor chip opposing the one side of the first semiconductor chip, and a molding layer surrounding the stacked second semiconductor chips, the first heat sink, and the second heat sink.

According to another aspect of the inventive concept, a semiconductor package may include; a package base substrate, an interposer mounted on the package base substrate, a first stack structure mounted on the interposer, a second stack structure mounted on the interposer, a third semiconductor chip centrally mounted on the interposer between the first stack structure and the second stacked structure, wherein the each of the first stacked structure and the second stacked structure includes; a first semiconductor chip electrically connected to the interposer, stacked second semiconductor chips vertically disposed on the first semiconductor chip, a first dummy chip horizontally disposed on the interposer to one side of the first semiconductor chip, a second dummy chip horizontally disposed on the interposer to another side of the first semiconductor chip opposing the one side of the first semiconductor chip, a first heat sink thermally-mounted on the first dummy chip and horizontally spaced apart to one side of the stacked second semiconductor chips, a second heat sink thermally-mounted on the second dummy chip and horizontally spaced apart to another side of the stacked second semiconductor chips opposing the one side of the stacked second semiconductor chips, a heat conductive layer disposed between the first dummy chip and the first semiconductor chip, and between the second dummy chip and the first semiconductor chip, and a molding layer surrounding the stacked second semiconductor chips, the first heat sink, and the second heat sink.

### BRIEF DESCRIPTION OF THE DRAWINGS

The making and use of the inventive concept may be more clearly understood upon consideration of the following detailed description together with the accompanying drawings in which:

FIG. 1 is a cross-sectional view of a semiconductor package according to embodiments of the inventive concept;

FIGS. 2A and 2B are plan (or top-down) views illustrating possible layouts for a semiconductor package according to embodiments of the inventive concept;

FIGS. 3A, 3B, 3C, 3D, 3E, 3F, 3G and 3H (hereafter collectively, “FIGS. 3A to 3H”) are related cross-sectional views illustrating in one example a method of manufacturing a semiconductor package according to embodiments of the inventive concept;

FIGS. 4A, 4B and 4C are cross-sectional views illustrating semiconductor packages according to embodiments of the inventive concept;

FIGS. 5 and 6 are respective cross-sectional views illustrating semiconductor packages according to embodiments of the inventive concept;

FIG. 7 is a cross-sectional view further illustrating in one example a method of manufacturing a semiconductor package according to embodiments of the inventive concept;

FIGS. 8A, 8B and 8C are cross-sectional views illustrating semiconductor packages according to embodiments of the inventive concept; and

FIG. 9 is a cross-sectional view illustrating a semiconductor package according to embodiments of the inventive concept.

### DETAILED DESCRIPTION

Throughout the written description and drawings, like reference numbers and labels are used to denote like or similar elements, components, features and/or method steps. Throughout the written description certain geometric terms may be used to highlight relative relationships between elements, components and/or features with respect to certain embodiments of the inventive concept. Those skilled in the art will recognize that such geometric terms are relative in nature, arbitrary in descriptive relationship(s) and/or directed to aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; overlay/underlay; etc.

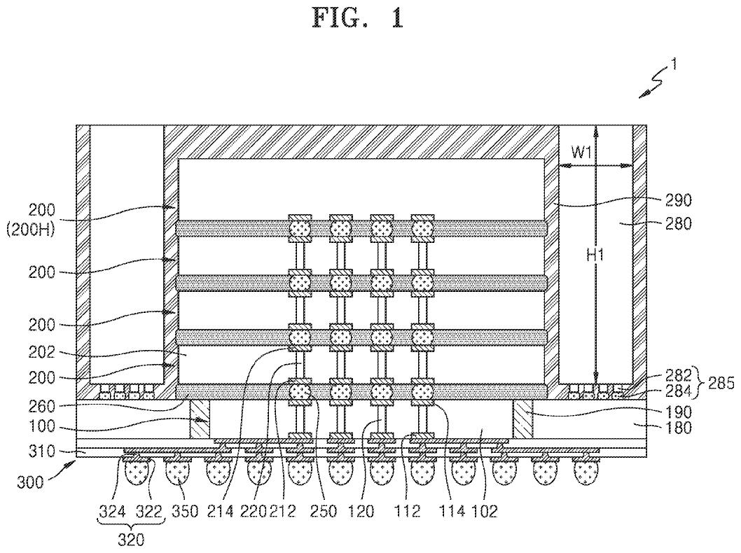

Figure (FIG. 1 is a cross-sectional view of a semiconductor package 1 according to embodiments of the inventive concept.

Referring to FIG. 1, the semiconductor package 1 may include an interposer 300 and a first semiconductor chip 100 mounted (e.g., mechanically assembled and/or electrically connected) on an upper surface of the interposer 300. A plurality of second semiconductor chips 200 may be vertically stacked on the first semiconductor chip 100 (e.g., stacked second semiconductor chips 200). At least two dummy chips 180 may be mounted on the interposer 300 and laterally (or horizontally) disposed in relation to the first semiconductor chip 100 (e.g., a first dummy chip may be horizontally disposed to one side of the first semiconductor chip 100 and a second dummy chip may be horizontally disposed to another side of the first semiconductor chip 100 opposing the one side). At least two heat sinks 280 may be respectively, thermally-mounted on the at least two dummy chips 180 (e.g., a first heat sink may be thermally-mounted on a first dummy chip to be horizontally disposed to one side of the stacked second semiconductor chips 200 and a second heat sink may be thermally-mounted on a second dummy chip to be horizontally disposed to another side of the stacked second semiconductor chips opposing the one side).

In the illustrated example of FIG. 1, it is assumed that four (4) second semiconductor chips 200 are vertically stacked on the first semiconductor chip 100. However, the scope of the inventive concept is not limited thereto, and in some embodiments the semiconductor package 1 may include multiple stacks of second semiconductor chips 200. In this regard, the second semiconductor chips 200 may be sequentially stacked on the first semiconductor chip 100 in a vertical direction to form a “stack” of second semiconductor chips 200. In some embodiment, respective active surfaces of the first semiconductor chip 100 and the second semiconductor chips 200 may downward toward the interposer 300.

In some embodiments, the interposer 300 may be a redistribution layer (RDL) interposer. That is, the interposer 300 may include at least one redistribution insulating layer 310 and a plurality of redistribution patterns 320 (e.g., redistribution line patterns 322 and/or redistribution vias 324). In some embodiments, the interposer 300 may include a stacked arrangement of redistribution insulating layers 310. The redistribution insulating layer 310 may include, for example, at least one of a photo imagable dielectric (PID) and a photosensitive polyimide (PSPI). The redistribution patterns 320 may include, for example, at least one metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and/or alloys of same. In some embodiments, the redistribution patterns 320 may be formed by stacking a metal/metal alloy on a seed layer including Ti, Ti nitride, or TiW.

The redistribution line patterns 322 may be arranged on at least one of an upper surface and a lower surface of the redistribution insulating layer 310. The redistribution vias 324 may extend (or pass) through at least one redistribution insulating layer 310 to respectively contact (and be electrically connected to) at least one of the redistribution line patterns 322. In some embodiments, one or more of the redistribution line patterns 322 may be integrally formed together with one or more of the redistribution vias 324. For example, each of the redistribution line patterns 322 along with each of the redistribution vias 324 contacting an upper surface of a redistribution line patterns 322 may be integrally formed.

In some embodiments, the redistribution vias 324 may have a tapered cross-sectional width (e.g., a distance measured in a first horizontal direction), such that each of the redistribution vias 324 extends downwardly with an increasingly-narrow width from a lower side to an upper side thereof. That is, the width of each of the redistribution vias 324 may increase in a direction away from the first semiconductor chip 100.

At least one of the redistribution line patterns 322 arranged on an upper surface of the interposer 300 may serve as a redistribution upper pad, and at least one of the redistribution line patterns 322 arranged on a lower surface of the interposer 300 may serve as a redistribution lower pad.

One or more of a plurality of first front connection pads 112 disposed on a lower surface of the first semiconductor chip 100 may be respectively connected to one or more of the redistribution upper pads, and one or more package connection terminals 350 may be respectively connected to one or more of the redistribution lower pads. The package connection terminals 350 may serve as an external connection terminals for the semiconductor package 1 that variously connect the package connection terminals 350 to one or more external elements and/or components. In some embodiments, each of the package connection terminals 350 may include a conductive bumps or a solder ball.

The first semiconductor chip 100 may include a memory cell array and may be, for example, a dynamic random access memory (RAM) (DRAM), a static RAM (SRAM), a flash memory, an electrically erasable/programmable read-only memory (ROM) (EEPROM), a phase-change RAM (PRAM), a magnetic RAM (MRAM), or a resistive RAM (RRAM). Alternately, the first semiconductor chip 100 may include one or more test logic circuit(s), such as a serial-parallel conversion circuit, a design-for-test (DFT) circuit, a joint test action group (JTAG) circuit, a memory built-in self-test (MBIST) circuit, or a signal interface circuit (e.g., a physical layer or PHY). Alternately, the first semiconductor chip 100 may include a buffer chip controlling, wholly or in part, the operation of one or more of the second semiconductor chips 200.

Each of the second semiconductor chips 200 may be, for example, a DRAM, a SRAM, a flash memory, an EEPROM, a PRAM, a MRAM, or a RRAM. That is, each of the second semiconductor chips 200 may include an array of memory cells.

Accordingly, in some embodiments, the first semiconductor chip 100 may be a buffer chip controlling a high bandwidth memory (HBM) DRAM. That is, the first semiconductor chip 100 may be a buffer chip controlling the operation of stacked second semiconductor chips 200—each of which is a HBM DRAM. Within such configurations and others, the first semiconductor chip 100 may be referred to as the buffer chip (or master chip), and each of the second semiconductor chips 200 may be referred to a memory chip (or a slave chip). In this regard, a vertically-stacked arrangement of second semiconductor (DRAM) chips 200 on the first semiconductor chip (buffer chip) 100 may be referred to as a HBM DRAM device.

The first semiconductor chip 100 may include a first substrate 102, first front connection pads 112 disposed on a front (or lower) surface of the first substrate 102, first rear connection pads 114 disposed on a rear (or upper) surface of the first substrate 102, and first through electrodes 120 respectively connecting one or more of the first front connection pads 112 with one or more of the first rear connection pads 114.

Each of the second semiconductor chips 200 may include a second substrate 202, second front connection pads 212, second rear connection pads 214, and second through electrodes 220 similarly disposed.

Each of the first substrate 102 and the second substrate 202 may include silicon (Si). Alternately, each of the first substrate 102 and the second substrate 202 may include a semiconductor element such as germanium (Ge) or a compound semiconductor such as silicon carbide (SiC), gallium arsenide (GaAs), indium arsenide (InAs), indium phosphide (InP), etc. Each of the first substrate 102 and the second substrate 202 may have an active surface and an inactive surface opposing the active surface. Each of the first substrate 102 and the second substrate 202 may variously include passive and/or active devices on its active surface (e.g., various microelectronics devices, metal-oxide-semiconductor field effect transistors (MOSFET) such as a complementary metal-insulator-semiconductor (CMOS) transistor, an image sensor such as system large scale integration (LSI) or an CMOS imaging sensor (CIS), a micro-electro-mechanical system (MEMS), a capacitor, an inductor, a resistor, a latch, a register, etc.

In some embodiments, any one of the first semiconductor chip 100 and the second semiconductor chips 200 may be implemented using more than one individual semiconductor device.

Thus, referring to FIG. 1, the first semiconductor device 100 may be operatively formed on the active surface of the first substrate 102, the first front connection pads 112 and the first rear connection pads 114 may be respectively arranged on the active surface and the inactive surface of the first substrate 102, and the first through electrodes 120 may vertically extend through at least a portion of the first substrate 102 to electrically connect the first front connection pads 112 and the first rear connection pads 114.

Each second semiconductor device may be operatively formed on the active surface of the second substrate 202, the second front connection pads 212 and the second rear connection pads 214 may be respectively arranged on the active surface and the inactive surface of the second substrate 202, and the second through electrodes 220 may vertically extend through at least a portion of the second substrate 202 to electrically connect the second front connection pads 212 and the second rear connection pads 214.

Here, the first through electrodes 120, the second through electrodes 220 and the package connection terminals 350 may be variously interconnected through one or more pads, terminals, and/or redistribution patterns.

Onto the first front connection pads 112 of the first semiconductor chip 100, among the redistribution line patterns 322, the redistribution upper pads may be connected. Onto the second front connection pads 212 of each of the second semiconductor chips 200, one or more chip connection terminals 250 may be attached. Here, the chip connection terminals 250 may be disposed between the first rear connection pads 114 of the first semiconductor chip 100 and the second front connection pads 212 of a lowermost one of the second semiconductor chips 200, and between the second front connection pads 212 of each of the remaining second semiconductor chips 200 among the second semiconductor chips 200 and the second rear connection pads 214 of another second semiconductor chip 200 disposed under each of the remaining second semiconductor chips 200 among the second semiconductor chips 200. In this manner, the first semiconductor chip 100 may be variously connected to at least one of the second semiconductor chips 200.

In some embodiments, an uppermost one (200H) of the second semiconductor chips 200, farthest from the first semiconductor chip 100 may not include the second rear connection pads 214 and the second through electrodes 220. Alternately or additionally, the uppermost second semiconductor chip 200H among the second semiconductor chips 200 and vertically, farthest disposed from the first semiconductor chip 100 may have a thickness greater than a thickness of the remaining ones of the second semiconductor chips 200.

An insulating adhesive layer 260 may be disposed between the first semiconductor chip 100 and the lowermost second semiconductor chip 200, as well as between vertically adjacent second semiconductor chips 200. Thus, the insulating adhesive layer 260 may be disposed on a lower surface of each of the second semiconductor chips 200 and to attach each of the second semiconductor chips 200 onto a lower substructure (e.g., the upper surface of the first semiconductor chip 100 or the upper surface of a lower second semiconductor chip 200). The insulating adhesive layer 260 may include at least one of, for example, a non-conductive film (NCF), a non-conductive paste (NCP), an insulating polymer, an epoxy resin, etc. The insulating adhesive layer 260 may substantially fill space(s) between the first semiconductor chip 100 and the lowermost second semiconductor chip 200 and between vertically adjacent second semiconductor chips 200, thereby substantially surrounding (or encompassing) related chip connection terminals 250.

In some embodiments, a first width of the first semiconductor chip 100 may be less than a second wide of each of the second semiconductor chips 200. (In the illustrated example of FIG. 1, it is assumed that each of the second semiconductor chips 200 has a same second width, but the inventive concept is not limited thereto and in other embodiments the lowermost second semiconductor chip 200 may have the second width and remaining second semiconductor chips may have a width less than or equal to the second width). Accordingly, each of the second semiconductor chips 200 (or at least the lowermost one of the second semiconductor chips 200) may include at least one “overhang portion” laterally extending beyond an outer edge of the first semiconductor chip 100.

In some embodiments, a heat conductive layer 190 may be disposed on at least one outer sidewall of the first semiconductor chip 100, wherein each of the second semiconductor chips 200 may horizontally extend over (e.g., vertically overlap) at least a portion of the heat conductive layer 190. And in some embodiments, the stack of second semiconductor chips 200 may vertically overlap an upper surface of the heat conductive layer 190 as well as at least a portion of one or more dummy chips 180. In this regard, two or more dummy chips 180 may be horizontally spaced apart from one another on the interposer 300 (e.g., in at least one of the first horizontal direction and a second horizontal direction intersecting the first horizontal direction), and also spaced apart from the first semiconductor chip 100 in one of the first horizontal direction and the second horizontal direction. Thus, in some embodiments, the first semiconductor chip 100 and the at least two dummy chips 180 may be horizontally coplanar on the upper surface of the interposer 300. Further in this regard, the heat conductive layer 190 may be disposed between adjacent one of the at least two dummy chips 180 and the first semiconductor chip 100.

Accordingly, in some embodiments, the upper surface of the first semiconductor chip 100 and upper surfaces of the at least two dummy chips 180 may be horizontally coplanar. In some embodiments, the upper surface of the first semiconductor chip 100, the upper surfaces of the at least two dummy chips 180, and the upper surface of the heat conductive layer 190 may be horizontally coplanar. For example, the first semiconductor chip 100 may have a vertical thickness (e.g., a distance measured in the vertical direction) equal to that of each of the at least two dummy chips 180, and the heat conductive layer 190 may completely fill spaces between each of the at least two dummy chips 180 and the first semiconductor chip 100.

Each of the at least two dummy chips 180 may include at least one semiconductor material, such as for example, Si, Ge, SiC, GaAs, InAs, InP, etc. For example, the at least two dummy chips 180 may include the same material as the first substrate 102.

In some embodiments, the heat conductive layer 190 may include at least one conductive material such a metal (e.g., a metal paste formed using a metal plating process). In other embodiments, the heat conductive layer 190 may include a thermal interface material (TIM) including at least one material providing electrical insulation (e.g., an epoxy resin).

Each of the at least two of the vertically-extending heat sinks 280 may be thermally-mounted (e.g., connected in such a manner and/or with such materials to readily transfer heat) on one of the at least two dummy chips 180. Thus, each of the at least two heat sinks 280 may be horizontally spaced apart from the stacked second semiconductor chips 200 when thermally-mounted on a respective one of the at least two dummy chips 180. In some embodiments, each of the at least two heat sinks 280 may be thermally-mounted on a respective one of the at least two dummy chips 180 using a heat transfer terminal 285.

Thus, in some embodiments, each of the at least two heat sinks 280 will not vertically overlap any portion of the first semiconductor chip 100. In some embodiments, each of the at least two heat sinks 280 may have a width less than that the width of each one of the at least two dummy chips 180. That is, a heat sink 280 may vertically overlap only a portion of the width of a corresponding dummy chip 180.

The at least two heat sinks 280 may include at least one semiconductor material, such as for example, Si, Ge, SiC, GaAs, InAs, InP, etc. For example, the at least two heat sinks 280 may include the same material as the first substrate 102 and/or the at least two dummy chips 180.

In some embodiments, each of the at least two dummy chips 180 and the at least two heat sinks 280 may be formed by vertically cutting off a portion of a bare wafer and then reducing the width and or thickness thereof. In this manner, each of the at least two dummy chips 180 and the at least two heat sinks 280 may substantially include only a semiconductor material (e.g., Si—excluding from consideration any naturally forming oxide layer).

A height H1 (e.g., a distance measured in the vertical direction) for each of the at least two heat sinks 280 may be substantially the same or greater than a stack height for the stacked second semiconductor chips 200. Here, the “stack height” may be measured from a lower surface of the lowermost second semiconductor chip 200 to an upper surface of the uppermost second semiconductor chip 200 among the stacked second semiconductor chips 200. In some embodiments, the height H1 of each of the at least two heat sinks 280 may range from about 500 μm to about 900 μm. A width W1 of each of the at least two heat sinks 280 may range from about 100 μM to about 400 μm. In some embodiments, an upper surface of each of the at least two heat sinks 280 may be at a “level” (e.g., a vertical distance measured from an arbitrarily selected horizontal surface, such as the upper surface of the interposer 300) greater (or higher) than a level of the upper surface of the uppermost second semiconductor chip 200H.

In some embodiments, each of the heat transfer terminals 285 may include heat transfer pillars 282 attached to the lower surface of one of the at least two heat sinks 280 and heat transfer solder layers 284 interposed between each of the heat transfer pillars 282 and the upper surface of a corresponding one of the at least two dummy chips 180. In some embodiments, the heat transfer pillar 282 may include Cu.

The semiconductor package 1 may further include a molding layer 290 substantially surrounding the second semiconductor chips 200 and the at least two heat sinks 280 on the first semiconductor chip 100, as well as the at least two dummy chips 180, and the heat conductive layer 190. The molding layer 290 may include, for example, an epoxy mold compound (EMC). In some embodiments, the molding layer 290 may cover side surfaces of the second semiconductor chips 200, side surfaces of the insulating adhesive layers 260, and the upper surface of the uppermost second semiconductor chip 200H. In some embodiments, the molding layer 290 may cover side surfaces of the at least two heat sinks 280, yet not cover the upper surfaces of the at least two heat sinks 280. For example, the upper surfaces of the at least two heat sinks 280 and an upper surface of the molding layer 290 may be coplanar.

In other embodiments, when the first semiconductor chip 100, the at least two dummy chips 180, and the heat conductive layer 190 do not cover the entire upper surface of the interposer 300, the molding layer 290 may cover exposed portions of the upper surface of the interposer 300 (e.g., portions not covered by the first semiconductor chip 100, the at least two dummy chips 180, and the heat conductive layer 190).

In the illustrated embodiment of FIG. 1, heat generated particularly by the first semiconductor chip 100 may be efficiently exhausted from the semiconductor package 1 through the combination of the at least two dummy chips 180 and the at least two heat sinks 280. And because heat generated by the first semiconductor chip 100 is principally exhausted through the at least two dummy chips 180, it will not be transferred to the stacked second semiconductor chips 200 by the heat conductive layer 190. This reduction in heat transferred to the stacked second semiconductor chips results in greater reliability of operation for the semiconductor package 1 over time.

In some more particular embodiments of the inventive concept, the semiconductor package 1 may be implemented to form a fan-out type package including the interposer 300 and the at least two dummy chips 180. With this arrangement, the overall width of the first semiconductor chip 100 on which the second semiconductor chips 200 are stacked may be less than a width of any one of the second semiconductor chips 200. Accordingly, a total net number of useful dies associated with first semiconductor chips 100 formed on a wafer may be increased, thereby reducing overall manufacturing costs for a production run of semiconductor packages 1.

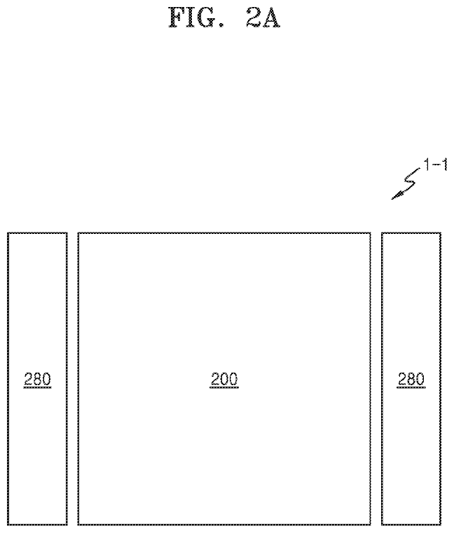

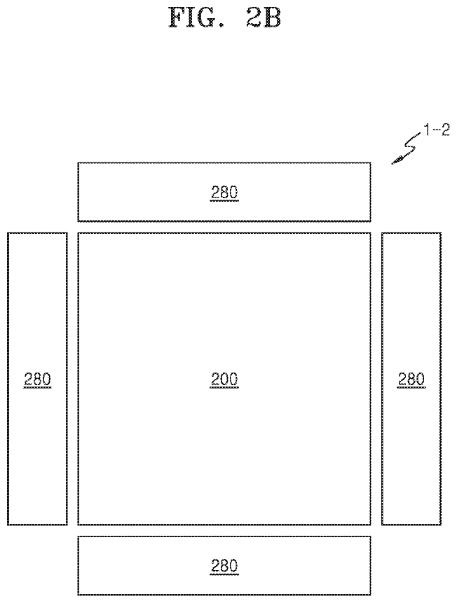

FIGS. 2A and 2B are respective, partial plan views of semiconductor packages 1-1 and 1-2 according to embodiments of the inventive concept.

Referring to FIG. 2A, the semiconductor package 1-1 may include a stack of second semiconductor chips 200 bracketed on opposing sides by two heat sinks 280, wherein each of the two heat sinks 280 is spaced apart from the stacked second semiconductor chips 200 in the horizontal direction (e.g., the first horizontal direction). That is, each of the two heat sinks 280 may be respectively disposed adjacent to a horizontally opposing side of the stacked second semiconductor chips 200.

In this regard, the semiconductor package 1-1 may include two dummy chips 180 like those illustrated in FIG. 1, wherein each dummy chip 180 is be vertically disposed under a corresponding heat sink 280, such that the heat sink 280 remains horizontally spaced apart from the stacked second semiconductor chips 200.

As illustrated in FIG. 2A, a length (e.g., a distance measured in the second horizontal direction) of each of the at least two heat sinks 280 may be substantially the same as (or less than, or greater than) a length of the second semiconductor chips 200.

In the illustrated example of FIG. 2A, only a single heat sink 280 is shown adjacent to an outer edge of the stacked second semiconductor chips 200. However, the inventive concept is not limited thereto, and two or more individual heat sinks 280 may be variously grouped along an outer edge of the stacked second semiconductor chips 200.

Referring to FIG. 2B, the semiconductor package 1-2 may include stacked second semiconductor chips 200 and at least four heat sinks 280, respectively disposed along one of four outer edges of stacked second semiconductor chips 200.

In this regard, the semiconductor package 1-2 may include four dummy chips 180 like those illustrated in FIG. 1, wherein each dummy chip 180 is be vertically disposed under a corresponding heat sink 280, such that the heat sink 280 remains horizontally spaced apart from the stacked second semiconductor chips 200.

In the illustrated example of FIG. 2B, only a single heat sink 280 is shown adjacent to each one of the four outer edges of the stacked second semiconductor chips 200. However, the inventive concept is not limited thereto, and two or more individual heat sinks 280 may be variously grouped and spaced apart along an outer edge of the stacked second semiconductor chips 200.

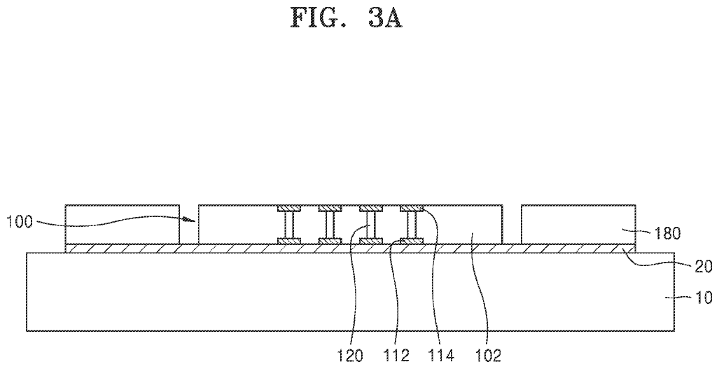

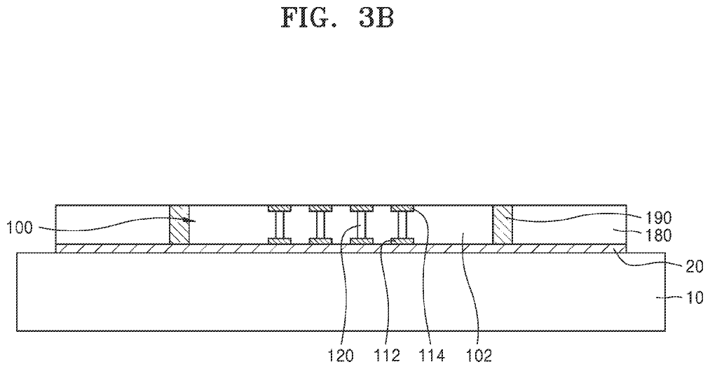

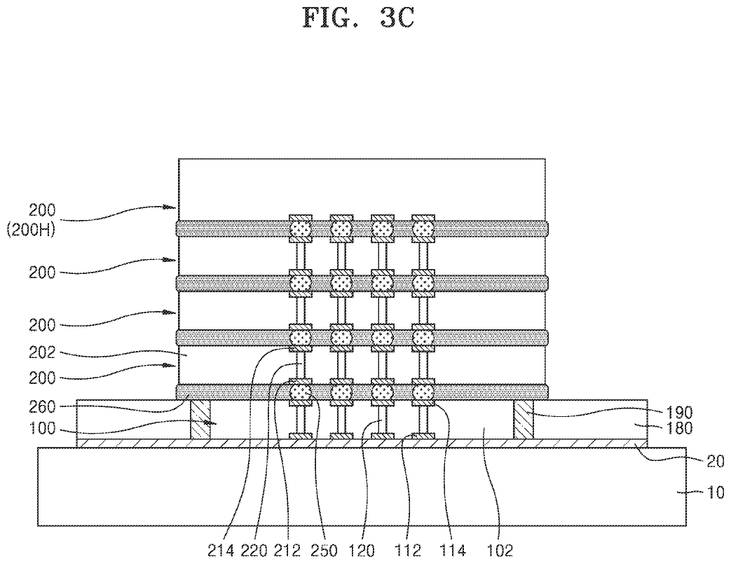

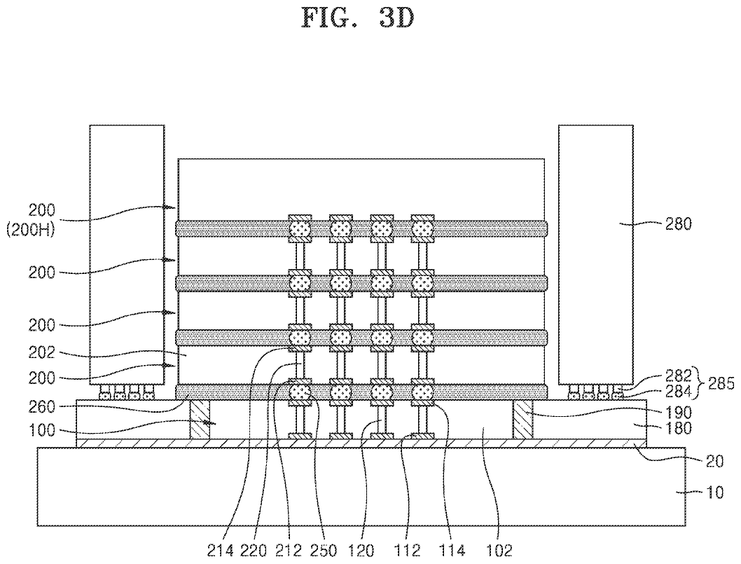

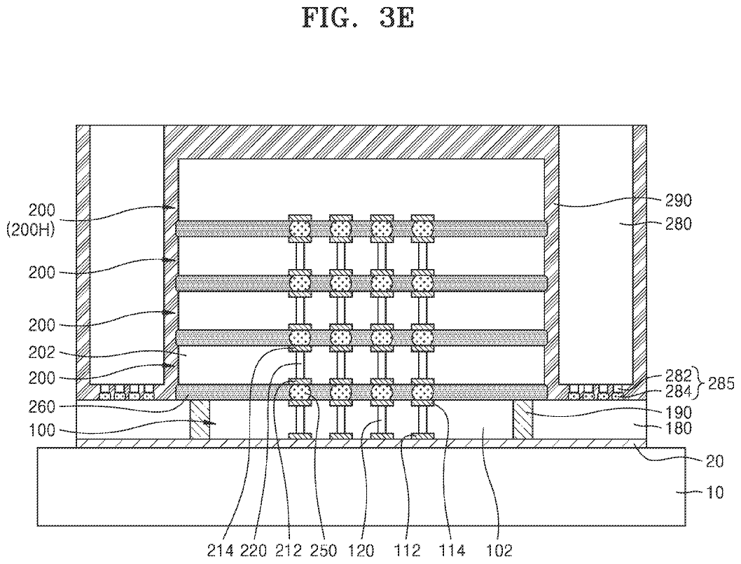

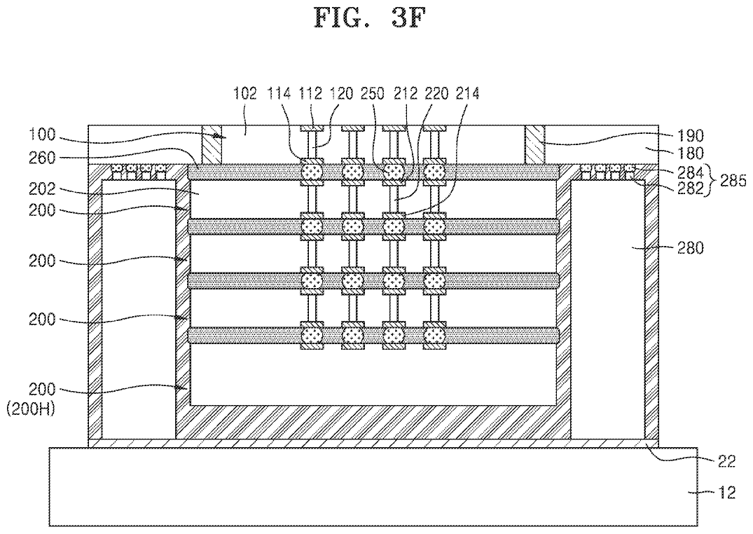

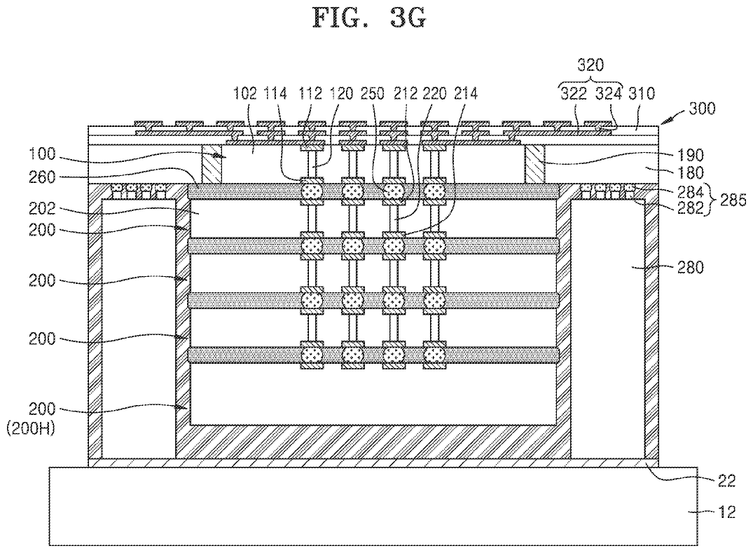

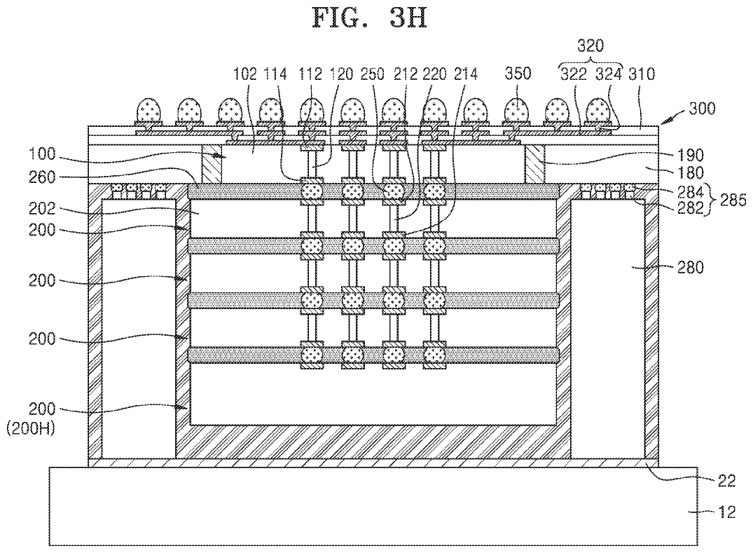

FIGS. 3A to 3H are related cross-sectional views illustrating in one example a method of manufacturing a semiconductor package according to embodiments of the inventive concept. More specifically, FIGS. 3A to 3H are related cross-sectional views illustrating a method of manufacturing the semiconductor package 1 of FIG. 1.

Referring to FIG. 3A, a first semiconductor chip 100 and at least two dummy chips 180 are attached onto a first support substrate 10. The at least two dummy chips 180 may be adjacent to two opposing edges or four edges of the first semiconductor chip 100 and may be horizontally spaced apart from the first semiconductor chip 100. For example, in the semiconductor package 1-1 illustrated in FIG. 2A, the two dummy chips 180 may be adjacent to the two opposite edges of the first semiconductor chip 100 and may be spaced apart from the first semiconductor chip 100 and, in the semiconductor package 1-2 illustrated in FIG. 2B, the four dummy chips 180 may be adjacent to the four edges of the first semiconductor chip 100 and may be spaced apart from the first semiconductor chip 100.

The first semiconductor chip 100 and the at least two dummy chips 180 may be attached onto the first support substrate 10 by a first release film 20. The first release film 20 may be a single layer or a multilayer including release layers respectively attached onto both sides of a backbone layer. The backbone layer may include, for example, thermoplastic polymer. The release layer may include, for example, copolymer of acryl and silicone.

Referring to FIG. 3B, a heat conductive layer 190 filling a space between each of the at least two dummy chips 180 and the first semiconductor chip 100 is formed.

In some embodiments, the heat conductive layer 190 may include a metal material. For example, the heat conductive layer 190 may be formed by filling the space between each of the at least two dummy chips 180 and the first semiconductor chip 100 with metal paste and hardening the metal paste. Alternatively, for example, the heat conductive layer 190 may be formed by filling the space between each of the at least two dummy chips 180 and the first semiconductor chip 100 with a metal material by a plating method such as immersion plating, electroless plating, or electroplating.

In other embodiments, the heat conductive layer 190 may include a TIM. The TIM may include, for example, mineral oil, grease, gap filler putty, a phase change gel, phase change material pads, or particle filled epoxy.

In some embodiments, after filling the space between each of the at least two dummy chips 180 and the first semiconductor chip 100 with the metal material or the TIM, by performing a planarizing process such as a chemical mechanical polishing (CMP) process, upper surfaces of the first semiconductor chip 100, the at least two dummy chips 180, and the heat conductive layer 190 may be coplanar with each other.

In FIGS. 3A and 3B, it is illustrated that the heat conductive layer 190 is formed after attaching the first semiconductor chip 100 having first rear connection pads 114 onto the first support substrate 10. However, the inventive concept is not limited thereto. In some embodiments, after attaching the first semiconductor chip 100 without use of the first rear connection pads 114 on the first support substrate 10, the heat conductive layer 190 may be previously formed and then, the first rear connection pads 114 may be formed.

Referring to FIG. 3C, second semiconductor chips 200 are stacked on the first semiconductor chip 100. The second semiconductor chips 200 may have one or more insulating adhesive layers 260 respectively attached to lower surfaces thereof and may be sequentially attached onto and stacked on the first semiconductor chip 100.

The second semiconductor chips 200 may be mounted on the first semiconductor chip 100 so that overhang portions of the second semiconductor chips 200 vertically overhang the first semiconductor chip 100. In some embodiments, the second semiconductor chips 200 may vertically overlap the first semiconductor chip 100 and at least a portion of the heat conductive layer 190. In some embodiments, the second semiconductor chips 200 may vertically overlap the first semiconductor chip 100, the heat conductive layer 190 and at least a portion of the at least two dummy chips 180.

Referring to FIG. 3D, at least two heat sinks 280 may be respectively and thermally-mounted on the at least two dummy chips 180. Here, the at least two heat sinks 280 may be horizontally spaced apart from the second semiconductor chips 200 and thermally-mounted on the at least two dummy chips 180. For example, each of the at least two heat sinks 280 may be thermally-mounted on a corresponding one of the at least two dummy chips 180 using an arrangement of heat transfer terminals 285.

Thus, the heat transfer terminals 285 may be attached to the lower surface of each of the at least two heat sinks 280 so that each of the at least two heat sinks 280 may be thermally-mounted to a corresponding one of the at least two dummy chips 180. The heat transfer terminals 285 may include heat transfer pillars 282 attached to the lower surface of each of the at least two heat sinks 280 and heat transfer solder layers 284 attached to the heat transfer pillars 282. The heat transfer solder layers 284 may contact each of the at least two dummy chips 180 and may be attached to each of the at least two dummy chips 180 using a thermal compression (TC) bonding method.

Referring to FIG. 3E, on the first semiconductor chip 100, the at least two dummy chips 180, and the heat conductive layer 190, a molding layer 290 surrounding the second semiconductor chips 200 and the at least two heat sinks 280 is formed. The molding layer 290 may include, for example, EMC.

In some embodiments, the molding layer 290 may cover side surfaces of the second semiconductor chips 200, side surfaces of the insulating adhesive layers 260, and the upper surface of the uppermost second semiconductor chip 200H. In some embodiments, the molding layer 290 may cover side surfaces of the at least two heat sinks 280, yet not cover the upper surfaces of the at least two heat sinks 280. For example, the upper surfaces of the at least two heat sinks 280 and an upper surface of the molding layer 290 may be coplanar.

After forming the molding layer 290, the first support substrate 10 to which the first release film 20 is attached may be removed from the first semiconductor chip 100 and the at least two dummy chips 180.

Referring to FIG. 3F, after turning the result of FIG. 3E upside down, the result is attached onto a second support substrate 12. The at least two heat sinks 280 and the molding layer 290 may be attached onto the second support substrate 12 by a second release film 22. Because the second support substrate 12 and the second release film 22 may have the same configurations as those of the first support substrate 10 and the first release film 20 illustrated in FIG. 3A, detailed description thereof is omitted.

Referring to FIG. 3G, an interposer 300 is formed on the result of FIG. 3F. The interposer 300 may cover the first semiconductor chip 100, the at least two dummy chips 180, and the heat conductive layer 190 filling the space between each of the at least two dummy chips 180 and the first semiconductor chip 100.

The interposer 300 may include redistribution patterns 320 including at least one redistribution insulating layer 310, redistribution line patterns 322, and redistribution vias 324.

The redistribution insulating layer 310 may include, for example, PID or PSPI.

The redistribution patterns 320, including the redistribution line patterns 322 and the redistribution vias 324, may be formed using a plating process. For example, the redistribution patterns 320 may be formed using the plating process, such as an immersion plating process, an electroless plating process, and/or an electroplating process.

At least some of the redistribution line patterns 322 may be formed together with and integrated to some of the redistribution vias 324. For example, each of the redistribution line patterns 322 and each of the redistribution vias 324 contacting a lower surface of the redistribution line patterns 322, may be integrally formed. In some embodiments, the redistribution vias 324 may be tapered so that each of the redistribution vias 324 extends with a increasing width from a lower side to an upper side. That is, the width of each of the redistribution vias 324 may increase in a direction away from the first semiconductor chip 100.

The interposer 300 may be formed by alternating the redistribution insulating layer 310 at the same vertical level with the redistribution line pattern 322 at the same vertical level. In some embodiments, the interposer 300 may include stacked redistribution insulating layers 310.

Referring to FIG. 3H, the package connection terminals 350 may be attached to the lower surface of the interposer 300. The package connection terminals 350 may be attached through redistribution lower pads among the redistribution line patterns 322. In some embodiments, each of the package connection terminals 350 may include a conductive bump or a solder ball.

Then, by removing the second support substrate 12 to which the second release film 22 is attached from the at least two heat sinks 280 and the molding layer 290, the semiconductor package 1 illustrated in FIG. 1 may be completed.

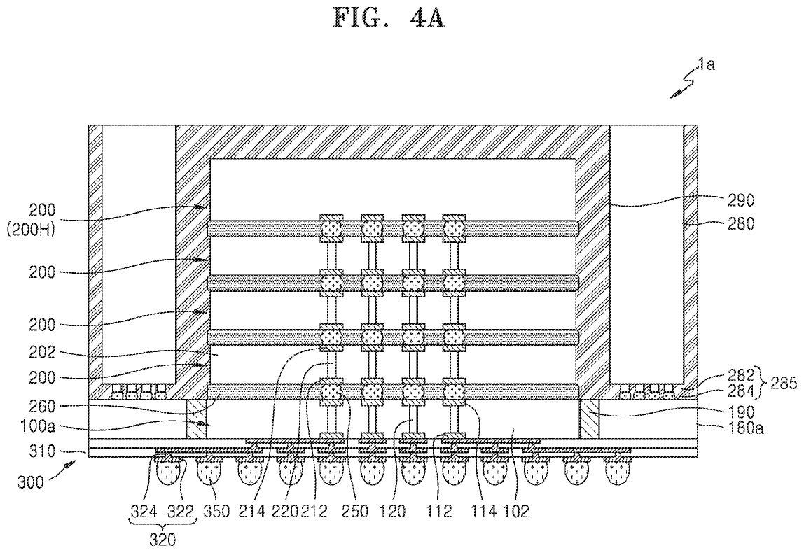

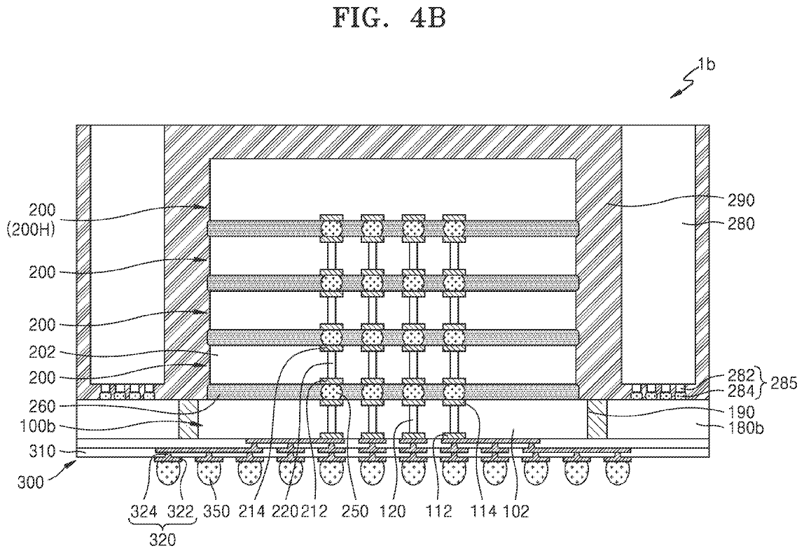

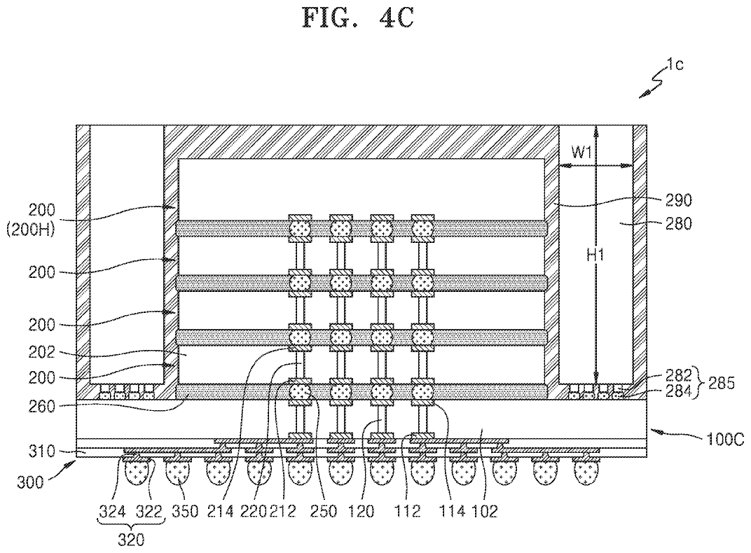

FIGS. 4A, 4B and 4C are cross-sectional views illustrating respective semiconductor packages 1a, 1b and 1c according to embodiments of the inventive concept.

Referring to FIG. 4A, the semiconductor package 1a may include the interposer 300, a first semiconductor chip 100a and at least two dummy chips 180a mounted on the interposer 300, the second semiconductor chips 200 stacked on the first semiconductor chip 100a, and the at least two heat sinks 280 thermally-mounted on the at least two dummy chips 180a.

The at least two dummy chips 180a may be horizontally spaced apart from the first semiconductor chip 100a and may mounted on the interposer 300. The heat conductive layer 190 may be disposed between each of the at least two dummy chips 180a and the first semiconductor chip 100a.

In some embodiments, the first semiconductor chip 100a may not include a memory cell, whereas each of the second semiconductor chips 200 may include a memory cell. For example, the first semiconductor chip 100a may be a buffer chip controlling the second semiconductor chips 200.

Here, the first semiconductor chip 100a may be substantially similar to the first semiconductor chip 100 of FIG. 1, except for its relative physical size. That is, a width of the first semiconductor chip 100a may be about the same as (instead of being less than) a width of the second semiconductor chips 200.

Here, an insulating adhesive layer 260 may be disposed between the first semiconductor chip 100a and the stacked second semiconductor chips 200. The insulating adhesive layer 260 may be attached onto the lower surface of each of the second semiconductor chips 200 and may attach each of the second semiconductor chips 200 to a substructure (e.g., the upper surface of the first semiconductor chip 100a or a vertically adjacent one of the second semiconductor chips 200). The insulating adhesive layer 260 may substantially fill spaces between the first semiconductor chip 100a and each of the second semiconductor chips 200 to surround (or encompass) the chip connection terminals 250.

Accordingly, a width of the first semiconductor chip 100a may be about the same as a width of each of the second semiconductor chips 200. Hence, an edge of each of the second semiconductor chips 200 may be substantially, vertically aligned with an edge of the first semiconductor chip 100a. For example, the lateral entirety of the first semiconductor chip 100a may overlap the lateral entirety of the stacked second semiconductor chips 200. Accordingly, in some embodiments, no portion of the second semiconductor chips 200 may vertically overlap any portion of the at least two dummy chips 180a and/or any portion of the heat conductive layer 190.

In some embodiments, the upper surface of the first semiconductor chip 100a and upper surfaces of the at least two dummy chips 180a may be coplanar. In some embodiments, the upper surface of the first semiconductor chip 100a, the upper surfaces of the at least two dummy chips 180a, and an upper surface of the heat conductive layer 190 may be coplanar. For example, the first semiconductor chip 100a may have a thickness equal to that of each of the at least two dummy chips 180a. The heat conductive layer 190 may fill a space between each of the at least two dummy chips 180a and the first semiconductor chip 100a.

Referring to FIG. 4B, the semiconductor package 1b may be substantially similar to the semiconductor package 1a of FIG. 4A, except for the relative width of a first semiconductor chip 100b in relation to a width of the first semiconductor chip 100a. Here, a width of the first semiconductor chip 100b is greater than a width of the second semiconductor chips 200.

Since the width of the first semiconductor chip 100b is greater than that of the stacked second semiconductor chips 200, the first semiconductor chip 100b will more than entirely vertically overlap the stacked second semiconductor chips 200. Thus, the second semiconductor chips 200 will not vertically overlap any portion of the at least two dummy chips 180b, nor any portion of the heat conductive layer 190.

Referring to FIG. 4C, the semiconductor package 1c may be substantially similar to the semiconductor package 1a of FIG. 4A, except that the heat conductive layer 190 is omitted.

Because the heat conductive layer 190 has been omitted, the overall width of the first semiconductor chip 100c may be reduced in relation to the width of the first semiconductor chip 100 of FIG. 1. Here, the width of the first semiconductor chip 100c may be substantially the same or greater than that of the second semiconductor chips 200.

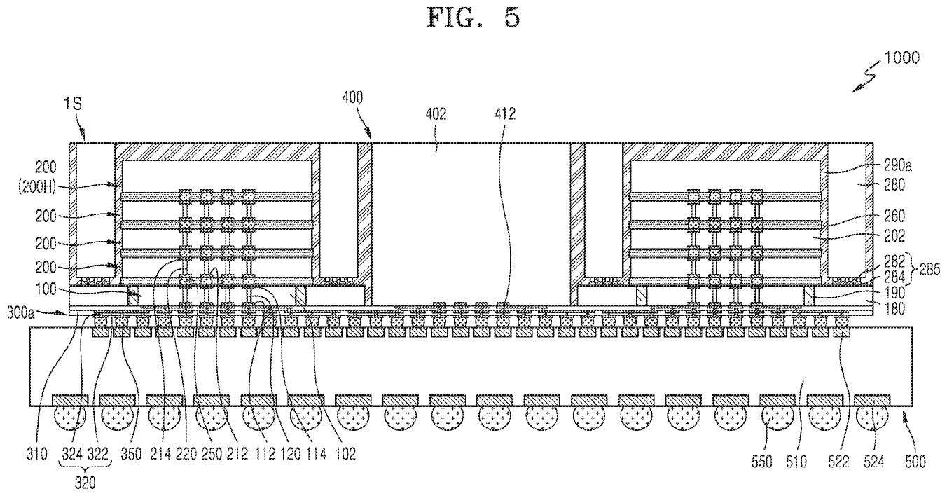

FIG. 5 is a cross-sectional view illustrating a semiconductor package 1000 according to embodiments of the inventive concept.

Referring to FIG. 5, the semiconductor package 1000 may include a package base substrate 500, an interposer 300a attached onto the package base substrate 500, a first semiconductor chip 100 attached onto the interposer 300a, second semiconductor chips 200 stacked on the first semiconductor chip 100, and a third semiconductor chip 400 mounted on the interposer 300a.

In the semiconductor package 1000, at least two stack structures 1S each including a first semiconductor chip 100, at least two dummy chips 180, a heat conductive layer 190 between each of the at least two dummy chips 180 and the first semiconductor chip 100, second semiconductor chips 200 stacked on the first semiconductor chip 100, at least two heat sinks 280 attached onto the at least two dummy chips 180, and heat transfer terminals 285 between each of the at least two dummy chips 180 and each of the at least two heat sinks 280 may be spaced apart from each other and mounted on the interposer 300a. Because each of the at least two stacked structures 1S attached onto the interposer 300a is similar to the stack structure illustrated in FIG. 1, which includes the first semiconductor chip 100 arranged on the interposer 300, the at least two dummy chips 180, the heat conductive layer 190 between each of the at least two dummy chips 180 and the first semiconductor chip 100, the second semiconductor chips 200 stacked on the first semiconductor chip 100, the at least two heat sinks 280 attached onto the at least two dummy chips 180, and the heat transfer terminals 285 between each of the at least two dummy chips 180 and each of the at least two heat sinks 280, detailed description thereof is omitted.

Because the interposer 300a includes at least one redistribution insulating layer 310 and a plurality of redistribution patterns 320 like the interposer 300 illustrated in FIG. 1, detailed description thereof is omitted. The third semiconductor chip 400 and the at least two stack structures 1S with the third semiconductor chip 400 therebetween, which are horizontally spaced apart from the third semiconductor chip 400, may be mounted on the interposer 300a. The stack structure 1S may be referred to as a memory stack, and the third semiconductor chip 400 may be referred to as a logic semiconductor chip. For example, the semiconductor package 1000 may include two, four, or eight or more stack structures 1S.

The third semiconductor chip 400 may include a third substrate 402 having a third semiconductor device formed on an active surface thereof and third front connection pads 412 arranged on the active surface of the third substrate 402. Because the third substrate 402 is similar to the first substrate 102 and the second substrate 202, detailed description thereof is omitted. The third front connection pads 412 of the third semiconductor chip 400 may contact and be electrically connected to some redistribution upper pads arranged on an upper surface of the interposer 300a among the redistribution line patterns 322 of the interposer 300a.

The third semiconductor chip 400 may include, for example, one of a central processing unit (CPU) chip, a graphics processing unit (GPU) chip, an application processor (AP) chip, an application specific integrated circuit (ASIC), or other processing chips.

The package base substrate 500 may include a base board layer 510 and first upper pads 522 and first lower pads 524 respectively arranged on an upper surface and a lower surface of the base board layer 510. The package base substrate 500 may include first wiring paths (not shown) electrically connecting the first upper pads 522 to the first lower pads 524 through the base board layer 510. In some embodiments, the package base substrate 500 may be a printed circuit board (PCB). For example, the package base substrate 500 may be a multilayer PCB.

The base board layer 510 may include at least one material for example phenol resin, epoxy resin, polyimide, frame retardant 4 (FR4), tetrafunctional epoxy, polyphenylene ether, epoxy/polyphenylene oxide, bismaleimide triazine (BT), thermount, cyanate ester, polyimide, and liquid crystal polymer. In some embodiments, the base board layer 510 may include, for example, polyester (PET), polyester terephthalate, fluorinated ethylene propylene (FEP), resin-coated paper, liquid polyimide resin, or polyethylene naphthalate (PEN). The base board layer 510 may be formed by stacking multiple base layers.

The first upper pads 522 and the first lower pads 524 may include at least one of for example, Cu, Ni, stainless steel, and BeCu. For example, the first upper pads 522 and the first lower pads 524 may include plated Cu. In some embodiments, Ni/Au may be provided on an opposite surface of the base board layer 510 of the first upper pads 522 and the first lower pads 524.

Each of the first wiring paths may include a buried conductive layer (not shown) and a conductive via (not shown). The first wiring paths may include at least one of for example, electrolytically deposited (ED) Cu, rolled-annealed (RA) Cu foil, stainless steel foil, Al foil, ultra-thin Cu foil, sputtered Cu, Cu alloys, Ni, stainless steel, or BeCu.

The base board layer 510 may further include a solder resist layer (not shown) exposing the first upper pads 522 and the first lower pads 524 on each of the upper surface and the lower surface. The solder resist layer may include at least one of a polyimide film, a polyester film, a flexible solder mask, a photoimageable coverlay (PIC), or photo-imagable solder resist. The solder resist layer may be formed by thermosetting ink coated by, for example, a silk screen print method or an inkjet method. The solder resist layer may be formed by removing a part of photosensitive solder resist coated by, for example, a screening method or a spray coating method by exposure and development and thermosetting the remaining part of photosensitive solder resist. The solder resist layer may be formed by laminating, for example, the polyimide film or the polyester film.

The package connection terminals 350 may be connected to the first upper pads 522 and external connection terminals 550 may be connected to the first lower pads 524. The package connection terminals 350 may electrically connect the interposer 300a to the package base substrate 500. The external connection terminals 550 connected to the first lower pads 524 may connect the semiconductor package 1000 to external circuitry.

The semiconductor package 1000 may further include a molding layer 290a surrounding the second semiconductor chips 200, the heat sinks 280, and the third semiconductor chip 400 on the interposer 300a. The molding layer 290a may include, for example, EMC. In some embodiments, the molding layer 290a may not cover upper surfaces of the heat sinks 280 and an upper surface of the third semiconductor chip 400. For example, the upper surfaces of the heat sinks 280, the upper surface of the third semiconductor chip 400, and an upper surface of the molding layer 290a may be coplanar.

In FIG. 5, the semiconductor package 1000 is illustrated as including the first semiconductor chip 100, the dummy chips 180, and the heat conductive layer 190. However, the inventive concept is not limited thereto. For example, the semiconductor package 1000 may include the first semiconductor chip 100a illustrated in FIG. 4A instead of the first semiconductor chip 100, the first semiconductor chip 100b illustrated in FIG. 4B instead of the first semiconductor chip 100, or the first semiconductor chip 100c illustrated in FIG. 4C instead of the first semiconductor chip 100, the dummy chips 180, and the heat conductive layer 190.

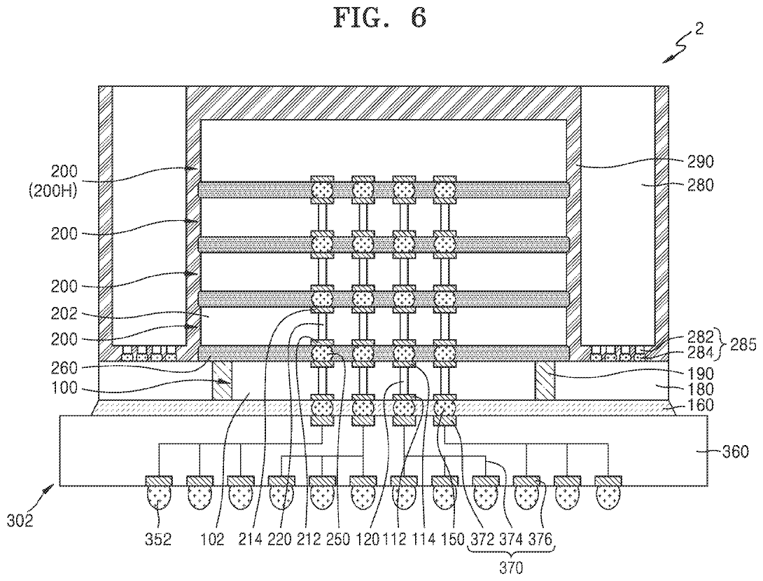

FIG. 6 is a cross-sectional view illustrating a semiconductor package 2 according to embodiments of the inventive concept.

Referring to FIG. 6, the semiconductor package 2 may include an interposer 302, a first semiconductor chip 100 and at least two dummy chips 180 attached onto the interposer 302, second semiconductor chips 200 stacked on the first semiconductor chip 100, and at least two heat sinks 280 attached onto the at least two dummy chips 180. The first semiconductor chip 100 and the stacked second semiconductor chips 200 may be sequentially disposed such that respective active surfaces face downward towards the interposer 302.

The interposer 302 may include a base layer 360, second upper pads 372 and second lower pads 376 respectively arranged on an upper surface and a lower surface of the base layer 360, and second wiring paths 374 electrically connecting the second upper pads 372 to the second lower pads 376.

In some embodiments, the base layer 360 may include at least one semiconductor material, such as glass, ceramic, or plastic. For example, in some embodiments, the interposer 302 may be a silicon interposer in which the base layer 360 is formed from a silicon semiconductor substrate.

In some embodiments, the second wiring paths 374 may include interposer through electrodes vertically extending through at least a portion of the base layer 360. The interposer through electrodes may electrically connect the second upper pads 372 and the second lower pads 376. Each of the interposer through electrodes may include a conductive plug passing through the base layer 360 and a conductive barrier layer surrounding the conductive plug. The conductive plug may be cylindrical and the conductive barrier layer may be cylindrical to surround side walls of the conductive plug. Via insulating layers may be disposed between the base layer 360 and the interposer through electrodes to surround side walls of the interposer through electrodes.

The second upper pads 372 and the second lower pads 376 may include a Cu alloy including Cu, Ni, stainless steel, or BeCu.

Interposer connection terminals 150 may be attached the second upper pads 372 to electrically connect the first semiconductor chip 100 to the interposer 302.

The package connection terminals 350 may be attached to the second lower pads 376. In some embodiments, the package connection terminals 350 may include at least one conductive material, such as, Cu, Al, Ag, Sn, Au, and solder. However, the inventive concept is not limited thereto. Each of the package connection terminals 350 may include a multilayer or a single layer. For example, each of the package connection terminals 350 may include an under-bump-material (UBM) layer and an interposer conductive cap on the UBM layer.

A footprint (e.g., an occupied lateral (or horizontal) surface area) for the interposer 302 may be greater than a footprint for a combination of the first semiconductor chip 100, the at least two dummy chips 180, and the heat conductive layer 190.

The interposer connection terminals 150 may be attached to the first front connection pads 112 of the first semiconductor chip 100. An underfill layer 160 may be disposed between the first semiconductor chip 100, the at least two dummy chips 180, and the heat conductive layer 190 and the interposer 302 and may substantially surround (or encompass) the interposer connection terminals 150.

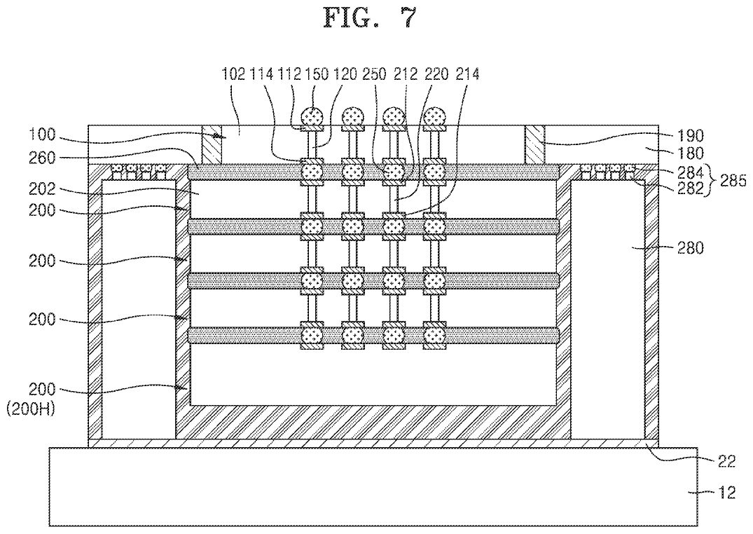

FIG. 7 is a cross-sectional view illustrating in one example a method of manufacturing a semiconductor package according to embodiments of the inventive concept. In this regard, FIG. 7, may be considered in relation to FIG. 6, as well as FIG. 3F previously described.

Referring to FIGS. 3F, 6 and 7, the interposer connection terminals 150 may be attached to the first front connection pads 112. The interposer connection terminals 150 may include at least one conductive material, such as for example, Cu, Al, Ag, Sn, Au, and solder. However, the inventive concept is not limited thereto. Each of the interposer connection terminals 150 may include a multilayer or a single layer. For example, each of the interposer connection terminals 150 may include an UBM layer and an interposer conductive cap on the UBM layer.

Then, after flipping the result of FIG. 7 upside down, by attaching the interposer connection terminals 150 to the second upper pads 372 of the interposer 302 (as shown in FIG. 6) and forming the underfill layer 160 between the first semiconductor chip 100, the at least two dummy chips 180, and the heat conductive layer 190 and the interposer 302, the semiconductor package 1000 may be formed. The underfill layer 160 may include, for example, NCP, insulating polymer, or epoxy resin.

Alternately, after flipping the result of FIG. 7 upside down, by forming the underfill layer 160 on the interposer 302 illustrated in FIG. 6 and having the interposer connection terminals 150 extend through the underfill layer 160 and contact the second upper pads 372 of the interposer 302, the semiconductor package 1000 may be formed. The underfill layer 160 may include, for example, NCF.

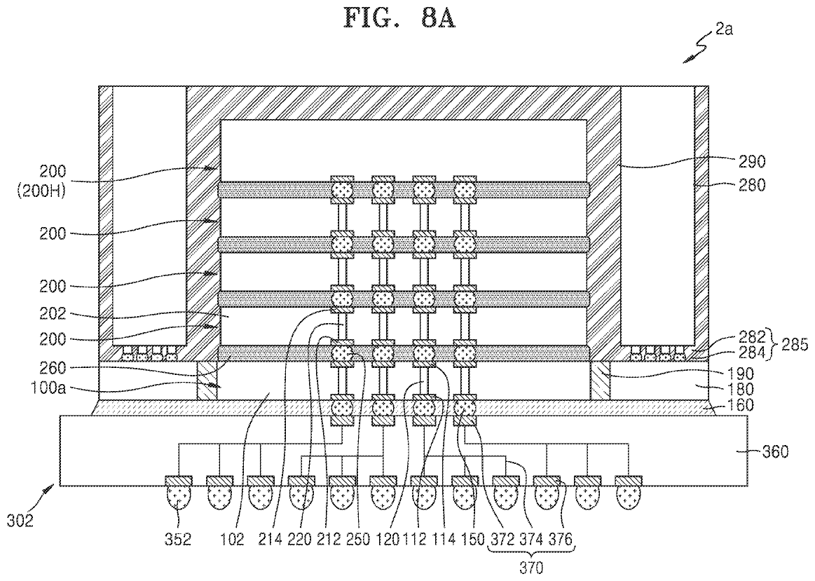

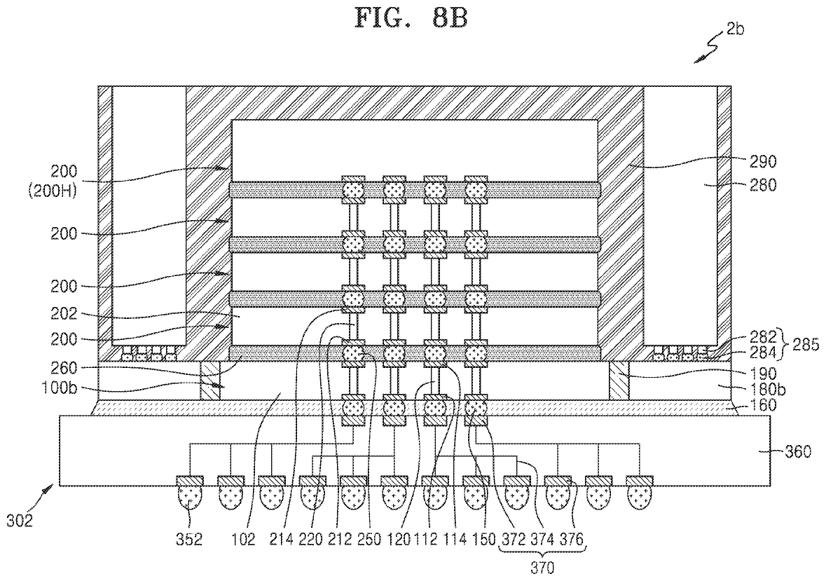

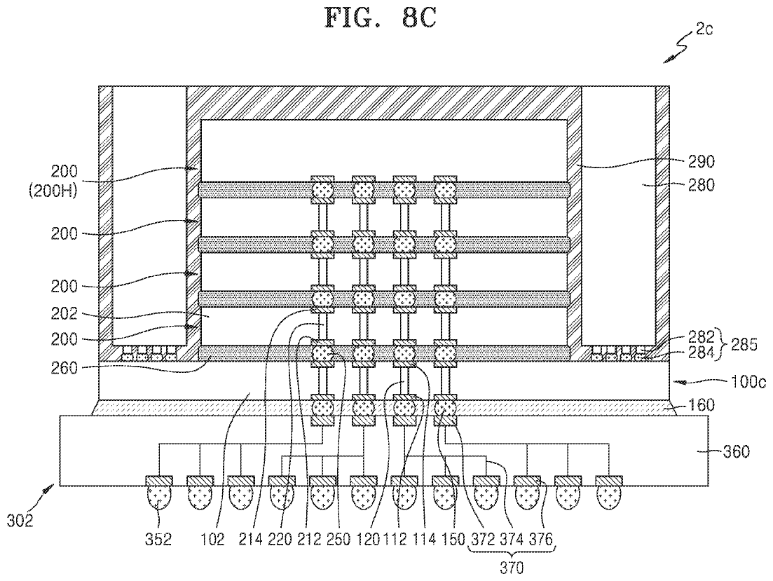

FIGS. 8A, 8B and 8C are respective cross-sectional views illustrating semiconductor packages 2a, 2b and 2c according to embodiments of the inventive concept. In this regard, FIGS. 8A, 8B and 8C may be consider in relation to FIGS. 4A, 4B and 4C, as well as FIG. 6.

Referring to FIG. 8A, the semiconductor package 2a may include an interposer 302, a first semiconductor chip 100a and at least two dummy chips 180 arranged on the interposer 302, second semiconductor chips 200 stacked on the first semiconductor chip 100a, and at least two heat sinks 280 attached onto the at least two dummy chips 180. The semiconductor package 2a may further include an underfill layer 160 between the first semiconductor chip 100a, the at least two dummy chips 180, and a heat conductive layer 190 and an interposer 302 and interposer connection terminals 150 extending (or passing) through the underfill layer 160 and connecting first front connection pads 112 of the first semiconductor chip 100a to second upper pads 372 of the interposer 302.

The at least two dummy chips 180 may be spaced apart (or laterally separated) from the first semiconductor chip 100a in the horizontal direction and may be attached onto the interposer 300. The heat conductive layer 190 may be between each of the at least two dummy chips 180 and the first semiconductor chip 100a.

In some embodiments, the first semiconductor chip 100a may not include a memory cell, whereas each of the second semiconductor chips 200 may include a memory cell. For example, the first semiconductor chip 100a may be a buffer chip for controlling the second semiconductor chips 200.

A width of the first semiconductor chip 100a may be equal to a width of each of the second semiconductor chips 200.

Referring to FIG. 8B, the semiconductor package 2b may include an interposer 302, a first semiconductor chip 100b and at least two dummy chips 180 arranged on the interposer 302, second semiconductor chips 200 stacked on the first semiconductor chip 100b, and at least two heat sinks 280 attached onto the at least two dummy chips 180. The semiconductor package 2b may further include an underfill layer 160 between the first semiconductor chip 100b, the at least two dummy chips 180, and a heat conductive layer 190 and an interposer 302 and interposer connection terminals 150 passing through the underfill layer 160 and connecting first front connection pads 112 of the first semiconductor chip 100b to second upper pads 372 of the interposer 302.

The at least two dummy chips 180 may be spaced apart from the first semiconductor chip 100b in the horizontal direction and may be attached onto the interposer 300. The heat conductive layer 190 may be between each of the at least two dummy chips 180 and the first semiconductor chip 100b.

In some embodiments, the first semiconductor chip 100b may not include a memory cell. The second semiconductor chips 200 may include a memory cell. For example, the first semiconductor chip 100b may be a buffer chip for controlling the second semiconductor chips 200.

A width of the first semiconductor chip 100b may be equal to a width of each of the second semiconductor chips 200.

Referring to FIG. 8C, the semiconductor package 2c may include an interposer 302, a first semiconductor chip 100c attached onto the interposer 302, second semiconductor chips 200 stacked on the first semiconductor chip 100c, and at least two heat sinks 280. The semiconductor package 2c may further include an underfill layer 160 between the first semiconductor chip 100c and an interposer 302 and interposer connection terminals 150 passing through the underfill layer 160 and connecting first front connection pads 112 of the first semiconductor chip 100c to second upper pads 372 of the interposer 302.

The semiconductor package 2c may omit the at least two dummy chips 180 and the heat conductive layer 190 included in each of the semiconductor packages 2, 2a, and 2b illustrated respectively in FIGS. 6, 8A, and 8B.

In some embodiments, the first semiconductor chip 100c may not include a memory cell. The second semiconductor chips 200 may include a memory cell. For example, the first semiconductor chip 100c may be a buffer chip for controlling the second semiconductor chips 200.

A width of the first semiconductor chip 100c may be greater than a width of each of the second semiconductor chips 200. The at least two heat sinks 280 may be attached onto the first semiconductor chip 100c. Each of the at least two heat sinks 280 may include heat transfer terminals 285 and may be attached onto the first semiconductor chip 100c. In some embodiments, the heat transfer terminals 285 may include heat transfer pillars 282 attached to the lower surface of each of the at least two heat sinks 280 and heat transfer solder layers 284 attached onto the heat transfer pillars 282 and contacting an upper surface of the first semiconductor chip 100c.

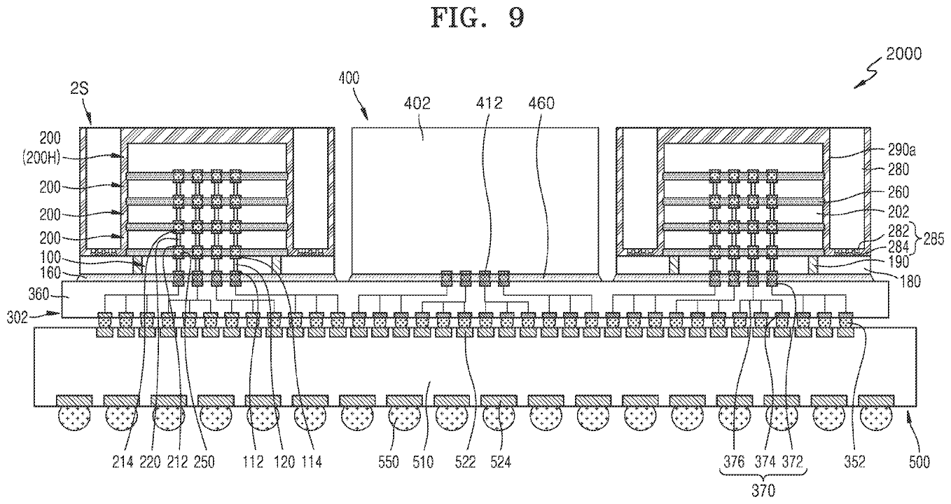

FIG. 9 is a cross-sectional view illustrating a semiconductor package 2000 according to embodiments of the inventive concept.

Referring to FIG. 9, the semiconductor package 2000 may include a package base substrate 500, an interposer 302a attached onto the package base substrate 500, a first-type semiconductor chip 100 mounted in mounted on the interposer 302a, second semiconductor chips 200 stacked on the first semiconductor chip 100, and a third semiconductor chip 400 mounted on the interposer 302a.

In the semiconductor package 2000, at least two stack structures 2S each including a first semiconductor chip 100, at least two dummy chips 180, a heat conductive layer 190 between each of the at least two dummy chips 180 and the first semiconductor chip 100, second semiconductor chips 200 stacked on the first semiconductor chip 100, at least two heat sinks 280 attached onto the at least two dummy chips 180, and heat transfer terminals 285 disposed between each of the at least two dummy chips 180 and each of the at least two heat sinks 280 may be spaced apart and may be attached onto the interposer 302a. Because each of the at least two stacked structures 2S attached onto the interposer 302a is similar to the stack structure illustrated in FIG. 6, which includes the first semiconductor chip 100 arranged on the interposer 302, the at least two dummy chips 180, the heat conductive layer 190 between each of the at least two dummy chips 180 and the first semiconductor chip 100, the second semiconductor chips 200 stacked on the first semiconductor chip 100, the at least two heat sinks 280 attached onto the at least two dummy chips 180, and the heat transfer terminals 285 disposed between each of the at least two dummy chips 180 and each of the at least two heat sinks 280, detailed description thereof is omitted.

Because the interposer 302a includes a base layer 360, second upper pads 372 and second lower pads 376 respectively arranged on an upper surface and a lower surface of the base layer 360, and second wiring paths 374 electrically connecting the second upper pads 372 to the second lower pads 376 like the interposer 302 illustrated in FIG. 6, detailed description thereof is omitted. The third semiconductor chip 400 and the at least two stack structures 2S with the third semiconductor chip 400 therebetween, which are horizontally spaced apart from the third semiconductor chip 400 may be attached onto the interposer 302a. The stack structure 2S may be referred to as a memory stack and the third semiconductor chip 400 may be referred to as a logic semiconductor chip. For example, the semiconductor package 2000 may include two, four, or eight or more stack structures 2S.

Between first front connection pads 112 of the first semiconductor chip 100 and third front connection pads 412 of the third semiconductor chip 400 and the second upper pads 372 of the interposer 302a, interposer connection terminals 150 may be interposed to electrically connect the first semiconductor chip 100 and the third semiconductor chip 400 to the interposer 302a.

Package connection terminals 350 may be connected to first upper pads 522 and external connection terminals 550 may be connected to first lower pads 524. The package connection terminals 350 may electrically connect the interposer 302a to the package base substrate 500. The external connection terminals 550 connected to the first lower pads 524 may connect the semiconductor package 2000 to external circuitry.

The semiconductor package 2000 may further include a molding layer 290a surrounding the second semiconductor chips 200, the heat sinks 280, and the third semiconductor chip 400 on the interposer 302a.

In FIG. 9, the semiconductor package 2000 is illustrated as including the first semiconductor chip 100, the dummy chips 180, and the heat conductive layer 190. However, the inventive concept is not limited thereto. For example, the semiconductor package 2000 may include the first semiconductor chip 100a illustrated in FIG. 8A instead of the first semiconductor chip 100, the first semiconductor chip 100b illustrated in FIG. 8B instead of the first semiconductor chip 100, or the first semiconductor chip 100c illustrated in FIG. 8C instead of the first semiconductor chip 100, the dummy chips 180, and the heat conductive layer 190.

While the inventive concept has been particularly shown and described with reference to embodiments thereof, it will be understood that various changes in form and details may be made therein without departing from the spirit and scope of the following claims.

What is claimed is:

1. A semiconductor package comprising:
an interposer;
a first semiconductor chip mounted on the interposer;
stacked second semiconductor chips vertically disposed on the first semiconductor chip;
a first dummy chip horizontally disposed on the interposer to one side of the first semiconductor chip;
a second dummy chip horizontally disposed on the interposer to another side of the first semiconductor chip opposing the one side of the first semiconductor chip;
a first heat sink thermally-mounted on the first dummy chip and horizontally spaced apart to one side of the stacked second semiconductor chips;
a second heat sink thermally mounted on the second dummy chip and horizontally spaced apart to another side of the stacked second semiconductor chips opposing the one side of the stacked second semiconductor chips; and
a molding layer surrounding the stacked second semiconductor chips, the first heat sink, and the second heat sink.

2. The semiconductor package of claim 1, further comprising:
a first heat transfer terminal disposed between the first dummy chip and the first heat sink and including heat transfer pillars attached to a lower surface of the first heat sink and heat transfer solder layers respectively attached to the heat transfer pillars; and
a second heat transfer terminal disposed between the second dummy chip and the second heat sink and including heat transfer pillars attached to a lower surface of the second heat sink and heat transfer solder layers respectively attached to the heat transfer pillars.

3. The semiconductor package of claim 2, further comprising:
a heat conductive layer disposed between the first dummy chip and the first semiconductor chip, and disposed between the second dummy chip and the first semiconductor chip.

4. The semiconductor package of claim 3, wherein the heat conductive layer includes a metal.

5. The semiconductor package of claim 3, wherein a width of the first semiconductor chip is less than a width of each second semiconductor chip among the stacked second semiconductor chips.

6. The semiconductor package of claim 5, wherein a lowermost second semiconductor chip among the stacked second semiconductors includes an overhang portion horizontally extending beyond an edge of the first semiconductor chip.

7. The semiconductor package of claim 6, wherein the overhang portion vertically overlays at least a portion of an upper surface of the heat conductive layer.

8. The semiconductor package of claim 6, wherein the overhang portion vertically overlays an entire upper surface of the heat conductive layer, at least a portion of an upper surface of the first dummy chip, and at least a portion of an upper surface of the second dummy chip.

9. The semiconductor package of claim 3, wherein an upper surface of the first dummy chip, an upper surface of the second dummy chip, an upper surface of the first semiconductor chip, and an upper surface of the heat conductive layer are horizontally coplanar.

10. The semiconductor package of claim 3, wherein a width of the first semiconductor chip is greater than a width of each second semiconductor chip among the stacked second semiconductor chips.

11. The semiconductor package of claim 2, wherein an upper surface of the first heat sink and an upper surface of the second heat sink are at a level higher than an upper surface of an uppermost second semiconductor chip among the stacked second semiconductor chips.

12. A semiconductor package comprising:
an interposer;
a first semiconductor chip mounted on the interposer;
stacked second semiconductor chips vertically disposed on the first semiconductor chip;
a first heat sink thermally-mounted on the interposer and horizontally spaced apart to one side of the first semiconductor chip;
a second heat sink thermally-mounted on the interposer and horizontally spaced apart to another side of the first semiconductor chip opposing the one side of the first semiconductor chip; and
a molding layer surrounding the stacked second semiconductor chips, the first heat sink, and the second heat sink.

13. The semiconductor package of claim 12, further comprising:
a first heat transfer terminal disposed between the interposer and the first heat sink and including heat transfer pillars attached to a lower surface of the first heat sink and heat transfer solder layers respectively attached to the heat transfer pillars; and
a second heat transfer terminal disposed between the interposer and the second heat sink and including heat transfer pillars attached to a lower surface of the second heat sink and heat transfer solder layers respectively attached to the heat transfer pillars.

14. The semiconductor package of claim 13, wherein a width of the first semiconductor chip is the same as a width of each second semiconductor chip among the stacked second semiconductor chips.

15. The semiconductor package of claim 13, wherein an upper surface of the first heat sink and an upper surface of the second heat sink are horizontally coplanar, and
the upper surface of the first heat sink and the upper surface of the second heat sink are at a level higher than an upper surface of an uppermost second semiconductor chip among the stacked second semiconductor chips.

16. The semiconductor package of claim 13, wherein the interposer is a redistribution layer interposer including at least one redistribution insulating layer and redistribution patterns, wherein the redistribution patterns include redistribution line patterns and redistribution vias.

17. The semiconductor package of claim 16, wherein the first semiconductor chip includes a first substrate, first front connection pads arranged on an active surface of the first substrate, first rear connection pads arranged on an inactive surface of the first substrate, and first through electrodes respectively connecting the first front connection pads and the first rear connection pads, and
at least one of the first front connection pads contacts at least one of the redistribution patterns.

18. The semiconductor package of claim 13, wherein each of the first heat sink and the second heat sink has a height of between 500 μM and 900 μM and a width of between 100 μM to 400 μm.

19. A semiconductor package comprising:
a package base substrate;
an interposer mounted on the package base substrate;
a first stack structure mounted on the interposer;
a second stack structure mounted on the interposer;
a third semiconductor chip centrally mounted on the interposer between the first stack structure and the second stacked structure,
wherein the each of the first stacked structure and the second stacked structure comprises:
a first semiconductor chip electrically connected to the interposer;
stacked second semiconductor chips vertically disposed on the first semiconductor chip;
a first dummy chip horizontally disposed on the interposer to one side of the first semiconductor chip;
a second dummy chip horizontally disposed on the interposer to another side of the first semiconductor chip opposing the one side of the first semiconductor chip;
a first heat sink thermally-mounted on the first dummy chip and horizontally spaced apart to one side of the stacked second semiconductor chips;
a second heat sink thermally-mounted on the second dummy chip and horizontally spaced apart to another side of the stacked second semiconductor chips opposing the one side of the stacked second semiconductor chips;
a heat conductive layer disposed between the first dummy chip and the first semiconductor chip, and between the second dummy chip and the first semiconductor chip; and
a molding layer surrounding the stacked second semiconductor chips, the first heat sink, and the second heat sink.

20. The semiconductor package of claim 19, wherein a width of the first semiconductor chip is less than a width of each one of the stacked second semiconductor chips, and
a lowermost second semiconductor chip among the stacked second semiconductors includes an overhang portion horizontally extending beyond an edge of the first semiconductor chip to vertically overlay an upper surface of the heat conductive layer, at least a portion of an upper surface of the first dummy chip, and at least a portion of an upper surface of the second dummy chip.
